(19) United States
(12) Patent Application Publication
(10) Pub. No.: US 2025/0293046 A1
(43) Pub. Date: Sep. 18, 2025

(54) PRIME STEP FOR METAL ETCH IN HIGH ASPECT-RATIO FEATURES

(71) Applicant: Applied Materials, Inc., Santa Clara, CA (US)

(72) Inventors: Baiwei Wang, Santa Clara, CA (US); Xiaolin C. Chen, San Ramon, CA (US); Rohan Puligoru Reddy, San Jose, CA (US); Wanxing Xu, Sunnyvale, CA (US); Zhenjiang Cui, San Jose, CA (US); Anchuan Wang, San Jose, CA (US)

(73) Assignee: Applied Materials, Inc., Santa Clara, CA (US)

(21) Appl. No.: 18/602,986

(22) Filed: Mar. 12, 2024

(51) Int. Cl. H01L 21/3213

(52) U.S. Cl. CPC H01L 21/32138

(57) ABSTRACT

Memory holes and other high aspect-ratio features in 3D NAND structures may include metal liners that are etched away as part of the manufacturing process. The etch process may include a prime step performed before a main etch process is performed. The prime step may include providing a helium precursor to treat the metal in a memory hole remove residue on the surface of the metal. The prime may also include providing a hydrogen precursor to further remove residue on the surface of the metal, and providing an oxygen-containing precursor and to form an oxidized portion of the metal. The prime may further include providing a halide precursor and contacting the oxidized portion of the metal to remove the oxidized portion of the metal from the sidewall of the memory hole, and treating the metal with hydrogen to remove residual metal oxide.

### TECHNICAL FIELD

The present technology relates to semiconductor processes and equipment. More specifically, the present technology relates to etching high-aspect ratio features.

### BACKGROUND

Integrated circuits are made possible by processes which produce intricately patterned material layers on substrate surfaces. Producing patterned material on a substrate requires controlled methods for removal of exposed material. Chemical etching is used for a variety of purposes including transferring a pattern in photoresist into underlying layers, thinning layers, or thinning lateral dimensions of features already present on the surface. Often it is desirable to have an etch process that etches one material faster than another facilitating, for example, a pattern transfer process. Such an etch process is said to be selective to the first material. As a result of the diversity of materials, circuits, and processes, etch processes have been developed with a selectivity towards a variety of materials.

Etch processes may be termed wet or dry based on the materials used in the process. A wet HF etch preferentially removes silicon oxide over other dielectrics and materials. However, wet processes may have difficulty penetrating some constrained trenches and also may sometimes deform the remaining material. Dry etches produced in local plasmas formed within the substrate processing region can penetrate more constrained trenches and exhibit less deformation of delicate remaining structures. However, local plasmas may damage the substrate through the production of electric arcs as they discharge.

Thus, there is a need for improved systems and methods that can be used to produce high quality devices and structures. These and other needs are addressed by the present technology.

### SUMMARY

In some embodiments, a method of pre-treating metal surfaces prior to etching in 3D NAND structures may include providing an oxygen-containing precursor to a semiconductor processing chamber, where a substrate may be positioned within the semiconductor processing chamber. The substrate may include a trench formed between columns and a metal formed in at least one of the columns. The method may also include contacting the metal with the oxygen-containing precursor to form an oxidized portion of the metal; providing a halide precursor to the semiconductor processing chamber; and contacting the oxidized portion of the metal with the halide precursor to remove the oxidized portion of the metal from a sidewall of the trench.

In some embodiments, a method of etching memory holes in 3D NAND structures may include priming an exposed metal within a high aspect-ratio structure defined on a substrate, where priming may include oxidizing the exposed metal to form a layer of metal oxide, etching the metal oxide with a halide precursor, and treating the exposed metal with hydrogen to remove residual halide material. The method may also include depositing a material along surfaces of the exposed metal within a high aspect-ratio structure defined on a substrate, where the material may be formed thicker along surfaces near an opening of the high aspect-ratio structure than along surfaces deeper within the high aspect-ratio structure. The method may also include repeatedly oxidizing a surface of the exposed metal and etching an oxidized portion of the exposed metal to conformally etch the exposed metal uniformly throughout the high aspect-ratio structure.

In some embodiments, a method of pre-treating metal surfaces prior to etching in 3D NAND structures may include providing a helium precursor to a semiconductor processing chamber, where a substrate may be positioned within the semiconductor processing chamber, the substrate may include a memory hole for a 3D NAND, and the helium precursor may treat a metal in the memory hole to bombard a surface of the metal and remove residue on the surface of the metal. The method may also include providing a hydrogen precursor to the semiconductor processing chamber to remove residue on the surface of the metal. The method may additionally include providing an oxygen-containing precursor and contacting the metal with the oxygen-containing precursor to form an oxidized portion of the metal. The method may further include providing a halide precursor to the semiconductor processing chamber and contacting the oxidized portion of the metal with the halide precursor to remove the oxidized portion of the metal from a sidewall of the memory hole; and treating the metal with hydrogen to remove residual metal oxide on a surface of the metal.

In any embodiments, any and all of the following features may be implemented in any combination and without limitation. Prior to providing the oxygen-containing precursor to the semiconductor processing chamber, a helium treatment may be provided to the metal to bombard a surface of the metal and remove residue on the surface of the metal. The helium treatment may provided without a plasma present. The helium treatment may alternatively be provided with a plasma present. The oxygen-containing precursor may include one or more of atomic oxygen, molecular oxygen (O2), N2O, NO, NO2, CO2, or ozone (O3). The oxidized portion of the metal may be less than or about 100 Å during the prime step. The halide precursor may include WF₆ or Cl₃, and contacting the oxidized portion of the metal with the halide precursor may be After contacting the oxidized portion of the metal with the halide precursor, the metal may be treated with hydrogen to remove residual metal oxide on a surface of the metal, wherein treating the metal with hydrogen does not substantially etch the metal. Oxidizing the surface of the exposed metal may include flowing a first fluorine-containing precursor and a secondary gas into a processing region of a semiconductor processing chamber, and contacting the exposed metal with the first fluorine-containing precursor and the secondary gas. The secondary gas may be a protective gas comprising oxygen or nitrogen. After repeatedly oxidizing the surface of the exposed metal and etching the oxidized portion of the exposed metal, a post-treatment of the high aspect-ratio structure may be performed using a fluorine-containing precursor. A plasma may be formed from the fluorine-containing precursor to remove any residual fluorine.

### BRIEF DESCRIPTION OF THE DRAWINGS

A further understanding of the nature and advantages of various embodiments may be realized by reference to the remaining portions of the specification and the drawings, wherein like reference numerals are used throughout the several drawings to refer to similar components. In some instances, a sub-label is associated with a reference numeral to denote one of multiple similar components. When reference is made to a reference numeral without specification to an existing sub-label, it is intended to refer to all such multiple similar components.

FIG. 1 shows a top plan view of one embodiment of an exemplary processing system according to some embodiments of the present technology.

FIG. 2A shows a schematic cross-sectional view of an exemplary processing chamber according to some embodiments of the present technology.

FIG. 2B shows a detailed view of a portion of the processing chamber illustrated in FIG. 2A according to some embodiments of the present technology.

FIG. 3 shows a bottom plan view of an exemplary showerhead according to some embodiments of the present technology.

FIG. 4 illustrates a semiconductor structure for a vertical 3D NAND, according to some embodiments.

FIG. 5 illustrates a flowchart of a method for treating a metal prior to performing an etch in a vertical 3D NAND structure, according to some embodiments.

FIG. 6 illustrates flow chart of a method of a depositing additional material on the structure, according to some embodiments.

FIG. 7 schematically illustrates deposition operations, according to some embodiments.

FIG. 8 illustrates a flowchart of a method for performing a fluorination etch with the protective gas, according some embodiments.

FIG. 9 illustrates structures in conjunction with the etch operations.

FIG. 10 illustrates a method for performing an oxidation etch, according to some embodiments.

FIGS. 11A-11B illustrate structures in conjunction with the etch operations.

### DETAILED DESCRIPTION

In transitioning from 2D NAND to 3D NAND, many process operations are modified from vertical to horizontal operations. Additionally, as 3D NAND structures grow in the number of cells being formed, the aspect ratios of memory holes and other structures increase, sometimes dramatically. During 3D NAND processing, stacks of placeholder layers and dielectric materials may form the inter-electrode dielectric or IPD layers. These placeholder layers may have a variety of operations performed to place structures before fully removing the material and replacing it with metal. Metallization may be performed in which a metal is formed along the structure and between layers of dielectric as portions of the memory cells. The metal may extend along sidewalls of the memory holes and within recessed portions, and a subsequent etch may be performed to separate the individual cells within the memory hole structure.

Many conventional technologies utilize etching processes to produce these structures that may be incapable of adequately performing at future process nodes. For example, as the number of cells within a structure increases to hundreds of cells, memory holes may be formed to a depth of several microns. Because of the robust etching of wet etches, the wet etch may begin etching the features closer to the top of the structure well before the bottom of the structure has been accessed by the etchant. Additionally, wet etching of small form factor structures may cause pattern collapse or deformation due to surface tension of the etchant. Using wet etchants may also create the need for subsequent operations to remove residues formed within the trenches or holes. Dry etching techniques may also be performed, however similar loading issues may occur. For example, because of the time needed to access deep within the trench, etching may already be occurring nearer the top of the structure. A ratio of the amount of metal etched at the top of the structure compared to an amount etched at the bottom of the structure, known as the top-to-bottom loading value, may be greater than or about 4 in some cases. Accordingly, top features may be over etched prior to etch completion or cell separation nearer the bottom of the structure.

The present technology overcomes these issues by performing a prime step to pretreat the metal surface and remove any surface residue or crust prior to the etching operations. A deposition process may then selectively deposited material such as tungsten, silicon, silicon oxide, titanium nitride, and so forth, over an oxide in order to deposit more material at the top of the trench than at the bottom. A fluorination etch may then be performed with a protective gas to etch the metal. An oxidation and halide etch may then be performed to etch into the tiers conformally of the memory. These steps may be cycled individually or collectively, and a post treatment step may be performed.

Although the remaining disclosure will routinely identify specific etching processes utilizing the disclosed technology, it will be readily understood that the systems and methods are equally applicable to deposition and cleaning processes as may occur in the described chambers. Accordingly, the technology should not be considered to be so limited as for use with etching processes or chambers alone. Moreover, although an exemplary chamber is described to provide foundation for the present technology, it is to be understood that the present technology can be applied to virtually any semiconductor processing chamber that may allow the operations described.

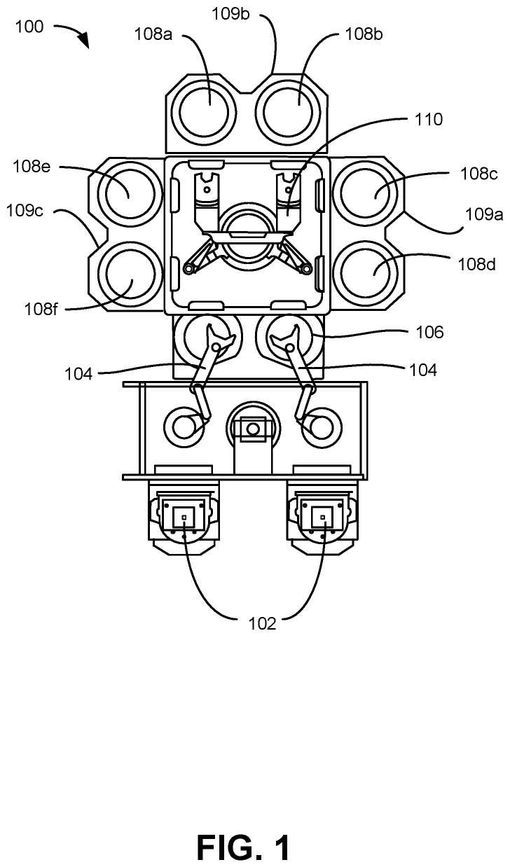

FIG. 1 shows a top plan view of one embodiment of a processing system 100 of deposition, etching, baking, and curing chambers according to embodiments. In the figure, a pair of front opening unified pods 102 supply substrates of a variety of sizes that are received by robotic arms 104 and placed into a low pressure holding area 106 before being placed into one of the substrate processing chambers 108a-f, positioned in tandem sections 109a-c. A second robotic arm 110 may be used to transport the substrate wafers from the holding area 106 to the substrate processing chambers 108a-f and back. Each substrate processing chamber 108a-f, can be outfitted to perform a number of substrate processing operations including the dry etch processes described herein in addition to cyclical layer deposition, atomic layer deposition, chemical vapor deposition, physical vapor deposition, etch, pre-clean, degas, orientation, and other substrate processes.

The substrate processing chambers 108a-f may include one or more system components for depositing, annealing, curing and/or etching a dielectric film on the substrate wafer. In one configuration, two pairs of the processing chambers, e.g., 108c-d and 108e-f, may be used to deposit dielectric material on the substrate, and the third pair of processing chambers, e.g., 108a-b, may be used to etch the deposited dielectric. In another configuration, all three pairs of chambers, e.g., 108a-f, may be configured to etch a dielectric film on the substrate. Any one or more of the processes described may be carried out in one or more chambers separated from the fabrication system shown in different embodiments. It will be appreciated that additional configurations of deposition, etching, annealing, and curing chambers for dielectric films are contemplated by system 100.

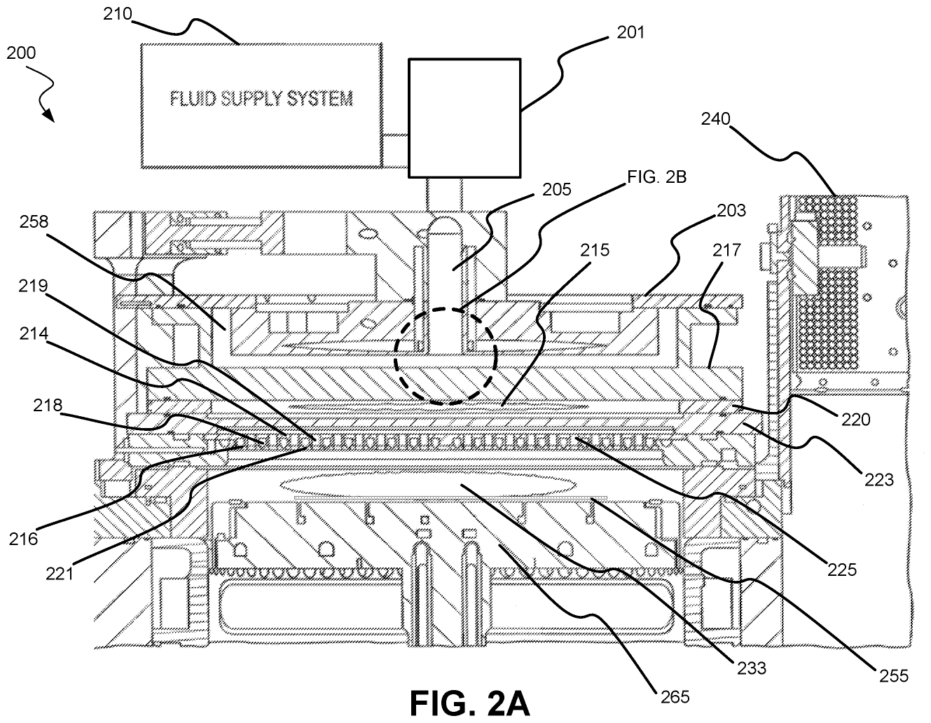

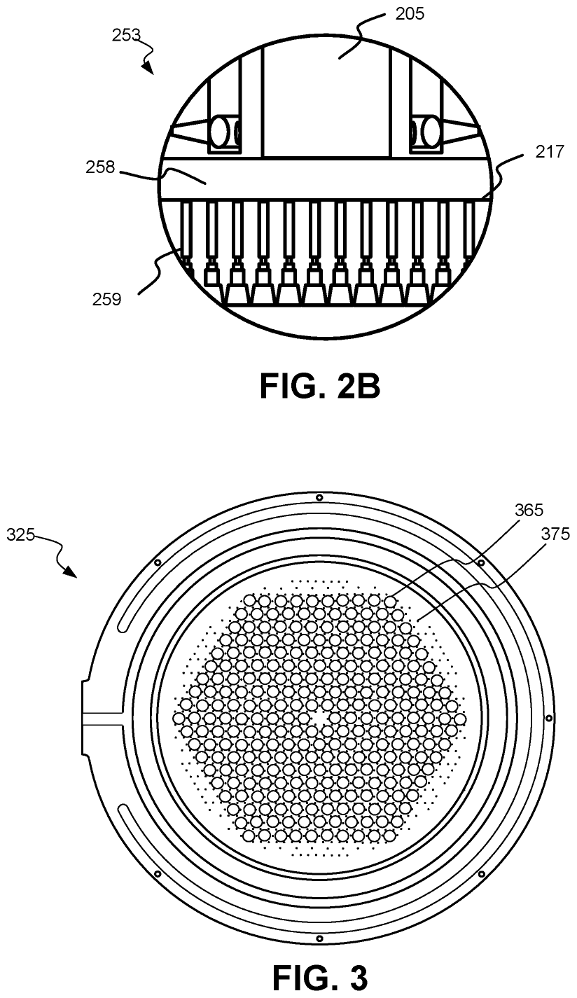

FIG. 2A shows a cross-sectional view of an exemplary process chamber system 200 with partitioned plasma generation regions within the processing chamber, and which may be configured to perform processes as described further below. During film etching, such as including titanium nitride, tantalum nitride, tungsten, silicon, polysilicon, silicon oxide, silicon nitride, silicon oxynitride, silicon oxycarbide, or other materials, a process gas may be flowed into the first plasma region 215 through a gas inlet assembly 205. A remote plasma system 201 may optionally be included in the system, and may process a first gas which then travels through gas inlet assembly 205. The inlet assembly 205 may include two or more distinct gas supply channels where the second channel may bypass the remote plasma system unit 201, if included.

A cooling plate 203, faceplate 217, ion suppressor 223, showerhead 225, and a substrate support 265, having a substrate 255 disposed thereon, are shown and may each be included according to embodiments. The pedestal 265 may have a heat exchange channel through which a heat exchange fluid flows to control the temperature of the substrate, which may be operated to heat and/or cool the substrate or wafer during processing operations. The wafer support platter of the pedestal 265, which may comprise aluminum, ceramic, or a combination thereof, may also be resistively heated in order to achieve relatively high temperatures, such as from up to or about 100° C. to above or about 1100° C., using an embedded resistive heater element.

The faceplate 217 may be pyramidal, conical, or of another similar structure with a narrow top portion expanding to a wide bottom portion. The faceplate 217 may additionally be flat as shown and include a plurality of through-channels used to distribute process gases. Plasma generating gases and/or plasma excited species, depending on use of the RPS 201, may pass through a plurality of holes, shown in FIG. 2B, in faceplate 217 for a more uniform delivery into the first plasma region 215.

Exemplary configurations may include having the gas inlet assembly 205 open into a gas supply region 258 partitioned from the first plasma region 215 by faceplate 217 so that the gases/species flow through the holes in the faceplate 217 into the first plasma region 215. Structural and operational features may be selected to prevent significant backflow of plasma from the first plasma region 215 back into the supply region 258, gas inlet assembly 205, and fluid supply system 210. The faceplate 217, or a conductive top portion of the chamber, and showerhead 225 are shown with an insulating ring 220 located between the features, which allows an AC potential to be applied to the faceplate 217 relative to showerhead 225 and/or ion suppressor 223. The insulating ring 220 may be positioned between the faceplate 217 and the showerhead 225 and/or ion suppressor 223 enabling a capacitively-coupled plasma to be formed in the first plasma region. A baffle may additionally be located in the first plasma region 215, or otherwise coupled with gas inlet assembly 205, to affect the flow of fluid into the region through gas inlet assembly 205. In some embodiments, additional plasma sources may be utilized including inductively-coupled plasma sources extending about the chamber or in fluid communication with the chamber, as well as additional plasma-generating systems.

The ion suppressor 223 may comprise a plate or other geometry that defines a plurality of apertures throughout the structure that are configured to suppress the migration of ionically-charged species out of the first plasma region 215 while allowing uncharged neutral or radical species to pass through the ion suppressor 223 into an activated gas delivery region between the suppressor and the showerhead. In embodiments, the ion suppressor 223 may comprise a perforated plate with a variety of aperture configurations. These uncharged species may include highly reactive species that are transported with less reactive carrier gas through the apertures. As noted above, the migration of ionic species through the holes may be reduced, and in some instances completely suppressed. Controlling the amount of ionic species passing through the ion suppressor 223 may advantageously provide increased control over the gas mixture brought into contact with the underlying wafer substrate, which in turn may increase control of the deposition and/or etch characteristics of the gas mixture. For example, adjustments in the ion concentration of the gas mixture can significantly alter its etch selectivity, e.g., SiNx:SiOx etch ratios, Si:SiOx etch ratios, etc. In alternative embodiments in which deposition is performed, it can also shift the balance of conformal-to-flowable style depositions for dielectric materials.

The plurality of apertures in the ion suppressor 223 may be configured to control the passage of the activated gas, i.e., the ionic, radical, and/or neutral species, through the ion suppressor 223. For example, the aspect ratio of the holes, or the hole diameter to length, and/or the geometry of the holes may be controlled so that the flow of ionically-charged species in the activated gas passing through the ion suppressor 223 is reduced. The holes in the ion suppressor 223 may include a tapered portion that faces the plasma excitation region 215, and a cylindrical portion that faces the showerhead 225. The cylindrical portion may be shaped and dimensioned to control the flow of ionic species passing to the showerhead 225. An adjustable electrical bias may also be applied to the ion suppressor 223 as an additional means to control the flow of ionic species through the suppressor.

The ion suppressor 223 may function to reduce or eliminate the amount of ionically charged species traveling from the plasma generation region to the substrate. Uncharged neutral and radical species may still pass through the openings in the ion suppressor to react with the substrate. It should be noted that the complete elimination of ionically charged species in the reaction region surrounding the substrate may not be performed in embodiments. In certain instances, ionic species are intended to reach the substrate in order to perform the etch and/or deposition process. In these instances, the ion suppressor may help to control the concentration of ionic species in the reaction region at a level that assists the process.

Showerhead 225 in combination with ion suppressor 223 may allow a plasma present in first plasma region 215 to avoid directly exciting gases in substrate processing region 233, while still allowing excited species to travel from chamber plasma region 215 into substrate processing region 233. In this way, the chamber may be configured to prevent the plasma from contacting a substrate 255 being etched. This may advantageously protect a variety of intricate structures and films patterned on the substrate, which may be damaged, dislocated, or otherwise warped if directly contacted by a generated plasma. Additionally, when plasma is allowed to contact the substrate or approach the substrate level, the rate at which oxide species etch may increase. Accordingly, if an exposed region of material is oxide, this material may be further protected by maintaining the plasma remotely from the substrate.

The processing system may further include a power supply 240 electrically coupled with the processing chamber to provide electric power to the faceplate 217, ion suppressor 223, showerhead 225, and/or pedestal 265 to generate a plasma in the first plasma region 215 or processing region 233. The power supply may be configured to deliver an adjustable amount of power to the chamber depending on the process performed. Such a configuration may allow for a tunable plasma to be used in the processes being performed. Unlike a remote plasma unit, which is often presented with on or off functionality, a tunable plasma may be configured to deliver a specific amount of power to the plasma region 215. This in turn may allow development of particular plasma characteristics such that precursors may be dissociated in specific ways to enhance the etching profiles produced by these precursors.

A plasma may be ignited either in chamber plasma region 215 above showerhead 225 or substrate processing region 233 below showerhead 225. Plasma may be present in chamber plasma region 215 to produce the radical precursors from an inflow of, for example, a fluorine-containing precursor or other precursor. An AC voltage typically in the radio frequency (“RF”) range may be applied between the conductive top portion of the processing chamber, such as faceplate 217, and showerhead 225 and/or ion suppressor 223 to ignite a plasma in chamber plasma region 215 during deposition. An RF power supply may generate a high RF frequency of 13.56 MHz but may also generate other frequencies alone or in combination with the 13.56 MHz frequency.

FIG. 2B shows a detailed view 253 of the features affecting the processing gas distribution through faceplate 217. As shown in FIGS. 2A and 2B, faceplate 217, cooling plate 203, and gas inlet assembly 205 intersect to define a gas supply region 258 into which process gases may be delivered from gas inlet 205. The gases may fill the gas supply region 258 and flow to first plasma region 215 through apertures 259 in faceplate 217. The apertures 259 may be configured to direct flow in a substantially unidirectional manner such that process gases may flow into processing region 233, but may be partially or fully prevented from backflow into the gas supply region 258 after traversing the faceplate 217.

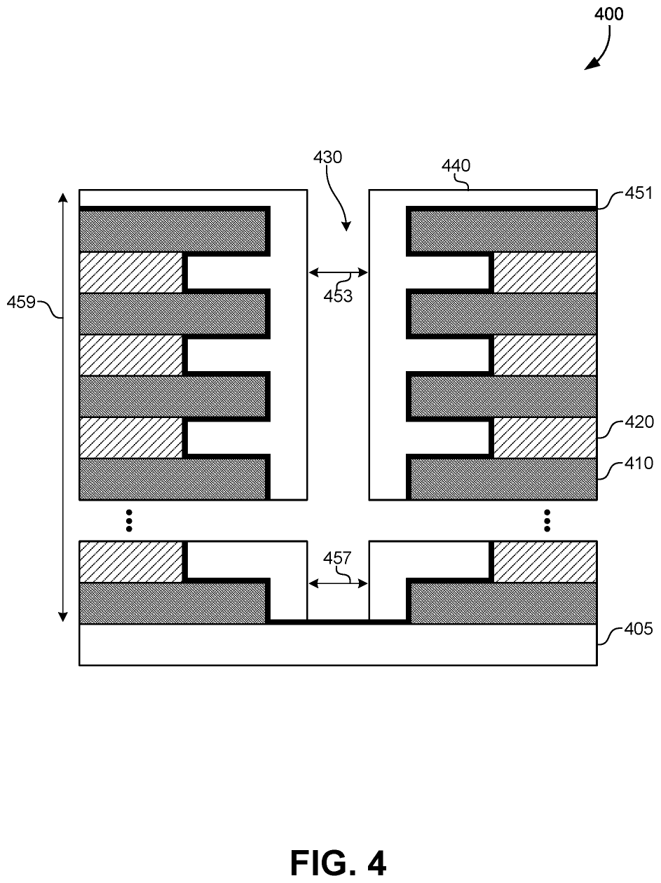

The gas distribution assemblies such as showerhead 225 for use in the processing chamber section 200 may be referred to as dual channel showerheads and are additionally detailed in the embodiments described in FIG. 3. The dual channel showerhead may provide for etching processes that allow for separation of etchants outside of the processing region 233 to provide limited interaction with chamber components and each other prior to being delivered into the processing region.

The showerhead 225 may comprise an upper plate 214 and a lower plate 216. The plates may be coupled with one another to define a volume 218 between the plates. The coupling of the plates may be so as to provide first fluid channels 219 through the upper and lower plates, and second fluid channels 221 through the lower plate 216. The formed channels may be configured to provide fluid access from the volume 218 through the lower plate 216 via second fluid channels 221 alone, and the first fluid channels 219 may be fluidly isolated from the volume 218 between the plates and the second fluid channels 221. The volume 218 may be fluidly accessible through a side of the gas distribution assembly 225.

FIG. 3 is a bottom view of a showerhead 325 for use with a processing chamber according to embodiments. Showerhead 325 may correspond with the showerhead 225 shown in FIG. 2A. Through-holes 365, which show a view of first fluid channels 219, may have a plurality of shapes and configurations in order to control and affect the flow of precursors through the showerhead 225. Small holes 375, which show a view of second fluid channels 221, may be distributed substantially evenly over the surface of the showerhead, even amongst the through-holes 365, and may help to provide more even mixing of the precursors as they exit the showerhead than other configurations.

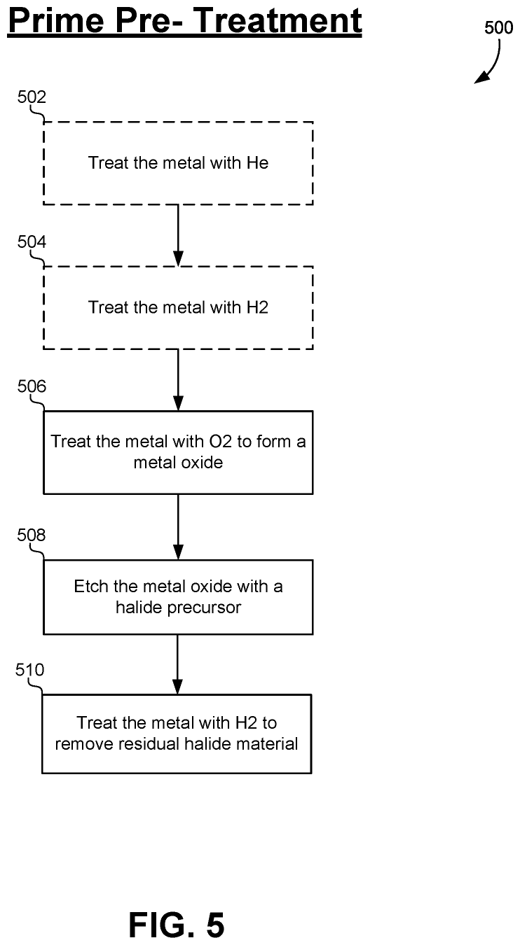

FIG. 4 illustrates a semiconductor structure 400 for a vertical 3D NAND, according to some embodiments. As illustrated in FIG. 4 a substrate 405 may have a plurality of stacked layers overlying the substrate 405, which may be silicon, silicon germanium, or other substrate materials. The layers may include IPD layers of ONO layers, including a dielectric material 410, which may be silicon oxide, in alternating layers with a placeholder material 420, which may be silicon nitride or polysilicon, for example. The placeholder material 420 may be or include material that will be removed to produce individual memory cells in subsequent operations. Although illustrated with only 4 to 5 layers of material, exemplary structures may include any of the numbers of layers including hundreds of layers of material, and it is to be understood that the figures are only schematics to illustrate aspects of the present technology. For example, the semiconductor structure 400 may include 10 or more layer pairs, 20 more layer pairs, 50 or more layer pairs, 100 or more layer pairs, and so forth. For example, a height 459 of the semiconductor structure 400 may be more than 10 μm, more than 20 μm, and so forth.

A trench 430, which may be a memory hole or aperture, may be defined through the stacked structure to the level of substrate 405. The trench 430 may be defined by sidewalls that may be composed of the alternating layers of the dielectric material 410 and the placeholder material 420. For example, the sidewalls may be a radius of the aperture or memory hole. Although only a single memory hole structure is illustrated, it is to be understood that exemplary substrates may include any number of memory structures across a substrate. By way of example, a width 453 of the trench 430 near the top of the trench 430 may be about 200 nm, and a width 457 of the trench 430 near the bottom of the trench 430 may be about 145 nm.

After recesses may be formed within the placeholder materials, a metal material 440 may be formed or deposited on the structure. A metal 440 may extend about the structure and within the memory holes and each recess formed in the placeholder materials as illustrated. The metal may be molybdenum, tungsten, or a number of other metals as may be used in 3D NAND or other semiconductor structures. Some embodiments may also include a liner 451 of materials such as silicon oxide, aluminum oxide, hafnium oxide, and so forth. The liner 451 may also include nitride barriers including a metal-containing oxide or nitride material. The substrate may be seated within a processing chamber, such as chamber 200 described above, and the methods described below may be performed for etching the metal within the high aspect-ratio feature. For example, features according to the present technology may be characterized by any aspect ratios or the height-to-width ratio of the structure, although in some embodiments the materials may be characterized by larger aspect ratios, which may not allow sufficient etching utilizing conventional technology or methodology as discussed above. For example, in some embodiments the aspect ratio of an exemplary structure, such as a memory hole as a non-limiting example, may be greater than or about 10:1, greater than or about 20:1, greater than or about 30:1, greater than or about 40:1, greater than or about 50:1, greater than or about 100:1, or greater.

The chamber discussed previously may be used in performing exemplary methods, including etching methods, although any number of chambers may be configured to perform one or more aspects used in embodiments of the present technology. In some embodiments, a pretreatment step may be performed on the semiconductor structure 400. As described in detail below, an etch process may be performed to remove a portion of the metal 440. By way of example, some 3D NAND structures may use molybdenum as the metal 440 in addition to the other metals described above. Therefore, the discussion below may use molybdenum only by way of example and not in a limiting fashion. Any other metal may be used, such as tungsten, titanium nitride, and/or the like. For example, the processes for forming the semiconductor structure may cause impurities within or surface contamination on the metal 440 that may make the etch process more difficult. For example, impurities may include molybdenum oxide, molybdenum oxyfloride, carbon-based residues, and/or other similar contaminants when molybdenum is used as the metal 440. Therefore, in order to improve the etching of the metal 440, some embodiments may add a “prime” step before the etch is performed in order to clean the metal 440.

### Prime Step

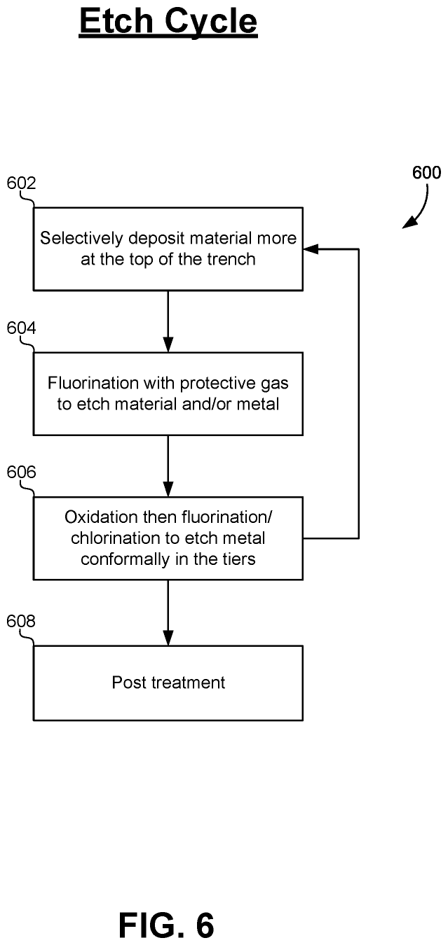

FIG. 5 illustrates a flowchart of a method 500 for treating a metal prior to performing an etch in a vertical 3D NAND structure, according to some embodiments. The pre treatment method may optionally first include treating the surface of the metal 440 with helium (502). For example, helium may be used to bombard the surface of the metal 440. This may clean the wafer. This bombardment process may also be used to heat the wafer. The helium treatment may be performed with or without a plasma and may primarily be used to remove any residue on the surface of the metal 440. Bombardment with helium ions has also been discovered to increase the temperature of the wafer and improve the uniformity of the temperature distribution on the wafer for subsequent processes.

The pre treatment method may optionally include further removing residue from the surface of the metal 440 by treating the surface of the metal 440 with hydrogen (504). This hydrogen treatment may be performed with or without the presence of a plasma. For example, the hydrogen may perform a reduction reaction on the surface of the metal 440 to further remove impurities and increase the temperature of the metal 440.

The pre treatment method may then include performing an oxidation reaction on the surface of the metal 440 using oxygen (506). The oxygen treatment may be applied with or without the presence of a plasma. By treating the surface of the metal 440 with oxygen, a metal oxide may be formed on the surface of the metal 440. For example, high temperatures may be applied with the oxygen in the absence of a plasma in order to form the metal oxide. Alternatively, a plasma may be applied with the oxygen to form the metal oxide.

The oxygen treatment may be performed by providing an oxygen-containing precursor. The oxygen-containing precursor may include a variety of fluids, and may include one or more of atomic oxygen, molecular oxygen (O₂), N₂O, NO, NO₂, CO₂, ozone (O₃), or any other oxygen-containing precursor that may similarly perform the oxidation operation. In some embodiments, the flow of the oxygen-containing precursors may be pulsed. The flow of the oxygen-containing precursors may be pulsed for time periods of less than or about 60 seconds in embodiments, and may be pulsed for time periods of less than or about 55 seconds, less than or about 50 seconds, less than or about 45 seconds, less than or about 40 seconds, less than or about 35 seconds, less than or about 30 seconds, less than or about 25 seconds, less than or about 20 seconds, less than or about 15 seconds, less than or about 10 seconds, less than or about 5 seconds, or less.

During the flow of the oxygen-containing precursors, the flow rate of the oxygen-containing precursor may be maintained at relatively high levels such that sufficient or even more than sufficient oxygen may be present from the top to the bottom of the trenches to fully oxidize the molybdenum connecting the molybdenum regions. In some embodiments, ample supply of oxygen may further improve the uniformity of the thickness of the molybdenum oxide layer formed inside the trenches. The uniformity may occur in part due to the initial rapid oxidization occurring at the neat or clean molybdenum surface. Specifically, the method 500 may be performed after the metal (e.g., molybdenum, TiN, etc.) has been deposited inside the trenches but before any atmospheric exposure. The oxidation rate at the molybdenum surface may be sufficiently rapid that with ample supply of oxygen, the molybdenum proximate the bottom of the trenches may be almost simultaneously oxidized to a thickness that may be substantially the same as that of the molybdenum oxidized proximate the top of the trenches. As oxidation penetrates the surface of the metal, the oxidation rate may decrease dramatically, and may in some embodiments reach a saturation depth at which minimal or no further oxidation may continue to occur at chamber conditions. Accordingly, metal located at a location further from initial contact of the plasma effluents, such as at the bottom of the trench, may be oxidized to a similar or substantially similar depth as at the top of the trench despite the longer residence time at locations proximate the top of the trench.

In some embodiments, the initial rapid oxidization may produce a molybdenum oxide layer having a thickness of greater than or about 10 Å, greater than or about 15 Å, greater than or about 20 Å, greater than or about 25 Å, greater than or about 30 Å, greater than or about 35 Å, greater than or about 40 Å, greater than or about 50 Å, greater than or about 60 Å, greater than or about 70 Å, greater than or about 80 Å, greater than or about 90 Å, greater than or about 100 Å, or more, before the oxidization process slows down. In some embodiments, by adjusting the processing conditions, the initial rapid oxidization may produce a molybdenum oxide layer having a thickness of less than or about 100 Å, less than or about 90 Å, less than or about 80 Å, less than or about 70 Å, less than or about 60 Å, less than or about 50 Å, less than or about 40 Å, or less. The thickness of the molybdenum oxide layer proximate an upper region of the trenches may differ from the thickness of the molybdenum oxide layer proximate a lower region of the trenches by less than or about 30%, less than or about 25%, less than or about 20%, less than or about 15%, less than or about 10%, less than or about 5%, less than or about 3%, less than or about 1%, or less in embodiments. Accordingly, a ratio of less than or about 1.3:1, less than or about 1.25:1, less than or about 1.2:1, less than or about 1.15:1, less than or about 1.1:1, less than or about 1.05:1, or a ratio of substantially or essentially 1:1 top to bottom loading of molybdenum oxidation as shown in FIG. 5B may be achieved utilizing method 500. Given the initial rapid oxidation, the flow of the oxygen-containing precursor may be maintained for time periods of less than or about 15 minutes, less than or about 10 minutes, less than or about 5 minutes, less than or about 3 minutes, less than or about 2 minutes, less than or about 90 seconds, less than or about 60 seconds, less than or about 50 seconds, less than or about 40 seconds, less than or about 30 seconds, less than or about 25 seconds, less than or about 20 seconds, less than or about 15 seconds, less than or about 10 seconds, less than or about 5 seconds, or less. In some embodiments, to facilitate sufficient oxidation, the flow of the oxygen-containing precursor may be maintained for time periods greater than or about 5 seconds, greater than or about 10 seconds, greater than or about 30 seconds, greater than or about 1 minute, greater than or about 5 minutes, greater than or about 10 minutes, greater than or about 15 minutes, or more. Accordingly, in some embodiments, the flow of the oxygen-containing precursor may be maintained between about 5 seconds and about 15 minutes, between about 30 seconds and about 10 minutes, between about 1 minute to about 5 minutes, or any other suitable time period.

The oxygen-containing precursor may also include any number of carrier gases, which may include nitrogen, helium, argon, or other noble, inert, or useful precursors. The carrier gases may be used to enhance uniform distribution of the oxygen-containing precursor inside the trenches, which may further improve top to bottom loading for the oxidation operation. In some embodiments, a flow rate of the carrier gas may be maintained less than or about 50% of the oxygen-containing precursor flow rate, or may be less than or about 40%, less than or about 30%, less than or about 20%, less than or about 10%, less than or about 5%, less than or about 3%, or less than or about 1% of the oxygen-containing precursor flow rate, or less. By adjusting the composition and/or the respective flow rates of the components of the oxygen-containing precursor, uniform delivery of the oxygen-containing plasma effluents inside the trench may be achieved, thereby further improving the uniformity of molybdenum oxidation from the top to the bottom of the trenches.

Each of these three steps (He, H2, and O2) may be carried out in the same chamber or in separate chambers. Each of these steps may also be performed using similar environmental conditions inside the chambers. For example, each step may be performed by flowing helium gas, hydrogen gas, or oxygen gas, respectively, into the chamber and applying a temperature that is greater than or about 200° C., greater than or about 250° C., greater than or about 300° C., greater than or about 350° C., greater than or about 400° C., greater than or about 450° C., greater than or about 500° C. Some embodiments may use a temperature range of between about 200° C. and about 300° C., between about 300° C. and about 400° C., between about 400° C. and about 500° C., between about 200° C. and about 500° C., and/or any other specific temperature ranges therein.

When performing any of these three steps using a plasma, the pressure may range from between about 0 torr and about 5 torr. For example, the pressure may range between about 0 torr and about 1 torr, between about 1 torr and about 2 torr, between about 2 torr and about 3 torr, between about 3 torr and about 4 torr, between about 4 torr and about 5 torr, and/or any specific ranges therein. When performing these steps without using a plasma, the pressure may range from between about 0 torr and about 50 torr. For example, the pressure may range from between about 0 torr and about 10 torr, between about 10 torr and about 20 torr, between about 20 torr and about 30 torr, between about 30 torr and about 40 torr, between about 40 torr and about 50 torr, and/or any specific ranges therein.

When a plasma is used as part of the treatment process, the plasma power applied may range from between about 0 W to about 500 W. For example, the plasma power may range from between about 0 W to about 100 W, between about 100 W to about 200 W, between about 200 W to about 300 W, between about 300 W to about 400 W, between about 400 W to about 500 W, and/or any specific ranges therein.

Flow rates for each of these three gases during these steps may range from between about 0 sccm to about 5000 sccm. For example, the flow rates may range from between 0 sccm to about 1000 sccm, between 1000 sccm to about 2000 sccm, between 2000 sccm to about 3000 sccm, between 3000 sccm to about 4000 sccm, between 4000 sccm to about 5000 sccm, and/or any specific ranges therein.

The treatment time for each of these three steps may range from between about one minute to about 10 minutes. For example, some embodiments may maximize the throughput of wafers by using a treatment time of between about two minutes and about five minutes. For example, a treatment time of about three minutes tends to generate a sufficient thickness of metal oxide. Increasing the treatment time above three minutes may further increase the thickness of the metal oxide, although at a slower rate than the oxide is formed in the first three minutes.

At this stage of the pre treatment, a metal oxide may have been formed on the substrate. The pre treatment method may then include treating the metal oxide with a halide precursor (508). For example, some embodiments may use a halide precursor such as tungsten fluoride (WF₆) in order to etch the metal oxide formed in the previous steps. Any other halide precursor may be used, such as boron trichloride (BCl₃). This step may be performed as a thermal treatment, and a plasma may not be needed in order to etch the metal oxide using the halide precursor. For example, this step may remove any MoOₓ or MoOₓF_{y} or other residues left on the surface of a metal such as molybdenum in order to clean and reveal a purer metal surface. Some embodiments may then purge the chamber with an inert gas after the halide precursor is used to etch the metal oxide. The same process be performed on other metals instead of Mo, such as TiN.

The oxidization operation (506) may be paused by halting the flow of the oxygen-containing precursor. In some embodiments, residual plasma effluents may be purge prior to the etch operation (508). The halide precursor may include a metal halide or other halogen-containing precursors that may interact with molybdenum oxide and/or liner material. In some embodiments, the halide precursor may be or include a chlorine-containing precursor or a fluorine-containing precursor. The halide precursor may include tungsten chloride, such as tungsten pentachloride, and/or tungsten fluoride, such as tungsten hexafluoride. The halide precursor may modify and interact with the metal oxide to form volatile substances, which may then be removed from the chamber. The volatile substances formed from the halide precursor and the metal oxide may include molybdenum oxychloride and/or molybdenum oxyfluoride. Once the metal oxide is removed by the halide precursor, the underlying oxide or nitride barriers may not be exposed and/or oxidized. For example, the etch operation may leave a substantial portion of the metal 440 still covering the alternating nitride/oxide layers of the semiconductor structure 400.

This step may be performed by flowing the halide precursor into the chamber and applying a temperature that is greater than or about 200° C., greater than or about 250° C., greater than or about 300° C., greater than or about 350° C., greater than or about 400° C., greater than or about 450° C., greater than or about 500° C. Some embodiments may use a temperature range of between about 200° C. and about 300° C., between about 300° C. and about 400° C., between about 400° C. and about 500° C., between about 200° C. and about 500° C., and/or any other specific ranges therein.

When performing this step without using a plasma in the chamber, the pressure may range from between about 0 torr and about 50 torr. For example, the pleasure may range between about 0 torr and about 10 torr, between about 10 torr and about 20 torr, between about 20 torr and about 30 torr, between about 30 torr and about 40 torr, between about 40 torr and about 50 torr, and/or any specific ranges therein.

Flow rates for the halide precursor during these steps may range from between about 0 sccm to about 5000 sccm. For example, the flow rates may range from between 0 sccm to about 1000 sccm, between 1000 sccm to about 2000 sccm, between 2000 sccm to about 3000 sccm, between 3000 sccm to about 4000 sccm, between 4000 sccm to about 5000 sccm, and/or any specific ranges therein.

The treatment time for the thermal treatment using the halide precursor may range from between about one minute and about 10 minutes. For example, some embodiments may maximize the throughput of wafers by using a treatment time of between about two minutes and about five minutes. In some embodiments, the treatment time for the halide precursor may be based on the treatment time for the oxidation step (506) described above. For example, a treatment time of about three minutes may remove the layer of metal oxide that was similarly formed with a treatment time of about three minutes. Since the halide precursor may selectively remove the metal oxide, the treatment time of the halide precursor may be configured to completely remove the thickness of the metal oxide formed above. For example, the halide precursor treatment may be applied for a time that is greater than an amount of time needed to completely etch the metal oxide, since over treating with a halide precursor will not further etch the metal after the oxide is removed.

Some embodiments may optionally further treat the metal in order to remove any residual halide material from the surface of the metal. Therefore, the method may further include treating the metal with hydrogen (510). For example, fluorine or molybdenum fluoride may have formed as a residue from the etching operation (508) described above. Some residual molybdenum oxide may also be present on the metal. Hydrogen may be introduced into the chamber to reduce the any halide residue and/or any oxygen residue left behind from previous steps. In contrast to the etching step above, this hydrogen treatment may be considered a surface treatment to remove any contaminants on the surface of the metal instead of etching away a layer of metal oxide or metal halide.

This hydrogen treatment step may be performed by flowing hydrogen gas into the chamber and applying a temperature that is greater than or about 200° C., greater than or about 250° C., greater than or about 300° C., greater than or about 350° C., greater than or about 400° C., greater than or about 450° C., greater than or about 500° C. Some embodiments may use a temperature range of between about 200° C. and about 300° C., between about 300° C. and about 400° C., between about 400° C. and about 500° C., between about 200° C. and about 500° C., and/or any other specific temperature ranges therein.

When performing this step using a plasma, the pressure may range from between about 0 torr and about 5 torr. For example, the pressure may range between about 0 torr and about 1 torr, between about 1 torr and about 2 torr, between about 2 torr and about 3 torr, between about 3 torr and about 4 torr, between about 4 torr and about 5 torr, and/or any specific ranges therein. When performing this step without using a plasma, the pressure may range from between about 0 torr and about 50 torr. For example, the pressure may range from between about 0 torr and about 10 torr, between about 10 torr and about 20 torr, between about 20 torr and about 30 torr, between about 30 torr and about 40 torr, between about 40 torr and about 50 torr, and/or any specific ranges therein.

When a plasma is used as part of the treatment process, the plasma power applied may range from between about 0 W to about 500 W. For example, the plasma power may range from between about 0 W to about 100 W, between about 100 W to about 200 W, between about 200 W to about 300 W, between about 300 W to about 400 W, between about 400 W to about 500 W, and/or any specific ranges therein.

Flow rates for the hydrogen gas during this step may range from between about 0 sccm to about 5000 sccm. For example, the flow rates may range from between 0 sccm to about 1000 sccm, between 1000 sccm to about 2000 sccm, between 2000 sccm to about 3000 sccm, between 3000 sccm to about 4000 sccm, between 4000 sccm to about 5000 sccm, and/or any specific ranges therein.

The treatment time for this step may range from between about one minute to about 10 minutes. For example, some embodiments may maximize the throughput of wafers by using a treatment time of between about two minutes and about five minutes.

These pretreatment or “prime” steps solve the problem of contamination on the metal prior to the etch into the high-aspect ratio features of the vertical 3D NAND. Specifically, it has been shown that these pretreatment steps improve the uniformity and predictability of the etch into the trench of the 3D NAND structure.

### Deposition

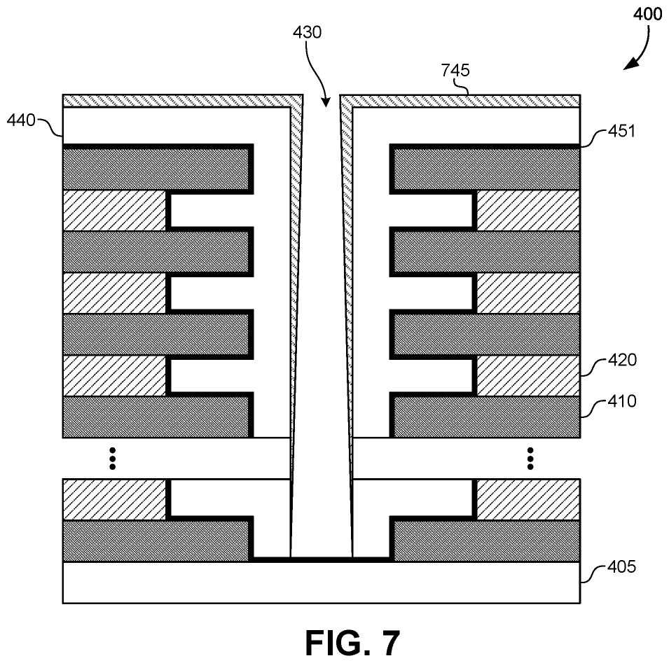

FIG. 6 illustrates flow chart of a method 600 of a depositing additional material on the structure, according to some embodiments. Method 600 may or may not involve optional operations to develop the semiconductor structure to a particular fabrication operation. It is to be understood that method 600 may be performed on any number of semiconductor structures or substrates, such as the semiconductor structure 400 illustrated in FIG. 4. In some embodiments, the method 600 may be performed on the semiconductor structure 400 after the method 500 to pretreat the semiconductor structure 400 has been performed.

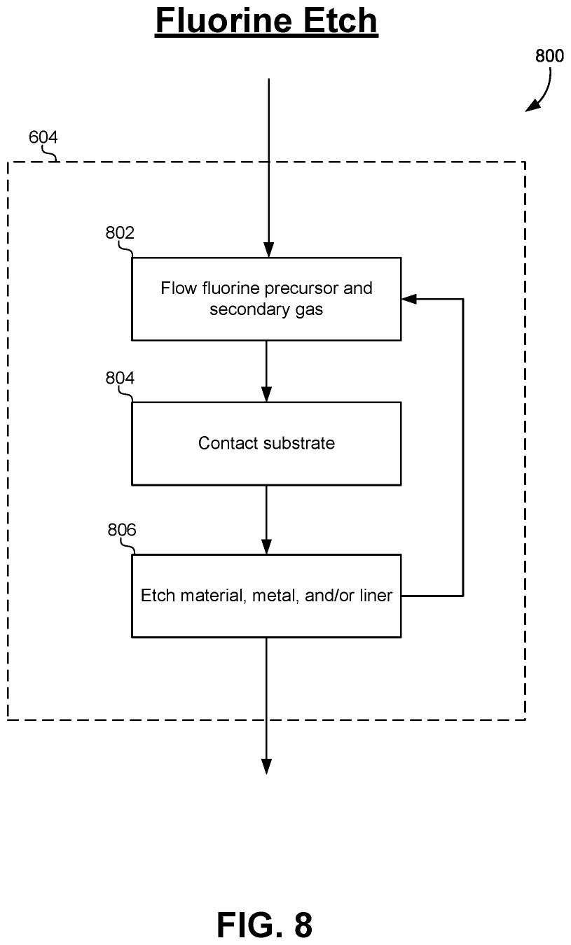

FIG. 7 schematically illustrates the deposition operations performed in method 600, according to some embodiments. Method 600 may include selectively depositing a material 745, such as a metal-containing material or a carbon-containing material, along surfaces of an exposed metal 440 within the trench 430, which may be a high aspect-ratio structure as previously described (602). In embodiments in which the material 745 is deposited prior to separation of the exposed metal 440, as discussed further below, the material 745 may be deposited along all exposed surfaces of exposed metal 440, which may extend above and/or into the trench 430. The material 745 may be the same or a different metal as the exposed metal 440, such as tungsten, molybdenum, or any other metal, and if carbon-containing material is deposited, the material may be carbon or any other carbon-containing material. In some embodiments, the material 745 may include other types of materials, such as W, Si, or SiOx over a metal 440 comprising TiN.

The material may be deposited by a plasma-enhanced deposition, although in some embodiments the deposition may be performed thermally, and the semiconductor processing region may be maintained plasma free during the depositing. In some embodiments one or more of the deposition operations may be performed in the same or a different chamber as subsequent etching operations. Additionally, the deposition may be performed in a first chamber and the etching may be performed in a second chamber, which may both be on the same platform, such as two chambers on system 100 discussed above. By utilizing different chambers, plasma deposition may be performed, or processing at different temperature may be more readily performed without adjusting processing conditions within the etching chamber. However, by performing a thermal deposition, the deposition may be performed selectively on the metal when a metal-containing material is deposited on the exposed metal 440.

The deposition may form a gradient thickness across exposed surfaces of the metal within the structure, where a greater thickness of material 745 may be formed along surfaces near an opening to the high aspect-ratio structure than along surfaces deeper within the high aspect-ratio structure, such as shown in FIG. 7. This may result a profile where the thickness of the material 745 is greater near the top of the trench 430 than at the bottom of the trench 430. Precursors utilized for the deposition may include any precursors that may facilitate deposition of a metal-containing material or a carbon-containing material. For example, exemplary precursors utilized for deposition may include tungsten-containing precursors, such as tungsten hexafluoride or tungsten oxytetrafluoride, molybdenum-containing precursors, such as molybdenum pentafluoride, molybdenum pentachloride, molybdenum oxyfluoride, or molybdenum oxychloride, among any other tungsten-containing or molybdenum-containing materials that may facilitate deposition on the exposed metal 440. Other embodiments may also use silicon-containing materials and/or oxygen-containing materials, depending on the type of material 745 being deposited.

To facilitate the reaction, which may be thermally produced or by a plasma-enhanced deposition, a hydrogen-containing material may be delivered to function as a reducing agent to allow the metal deposition to be performed. Exemplary hydrogen-containing materials may include diatomic hydrogen, disilane, or any other hydrogen-containing material. Because increased precursor proportions may contact surfaces higher within the trench 430 than lower within the trench, a deposition gradient may be produced, which may allow a controllable deposition along surfaces. Additionally, a carbon-containing material may be deposited instead of a metal-containing material, and carbon-containing precursors may include carbon-and-halogen-containing precursors that may be flowed with a hydrogen-containing reducing agent. Any carbon-and-fluorine or carbon-and-chlorine precursor may be used according to embodiments of the present technology.

Fluorination with Protective Gas

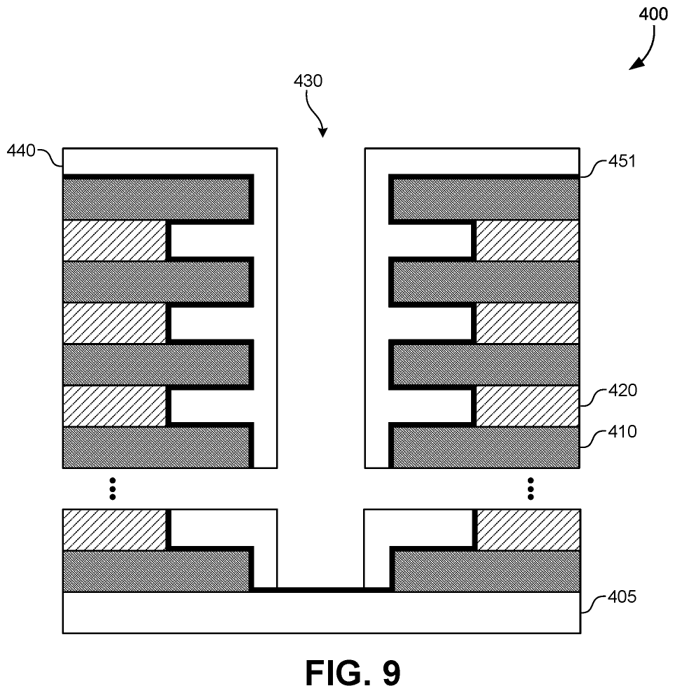

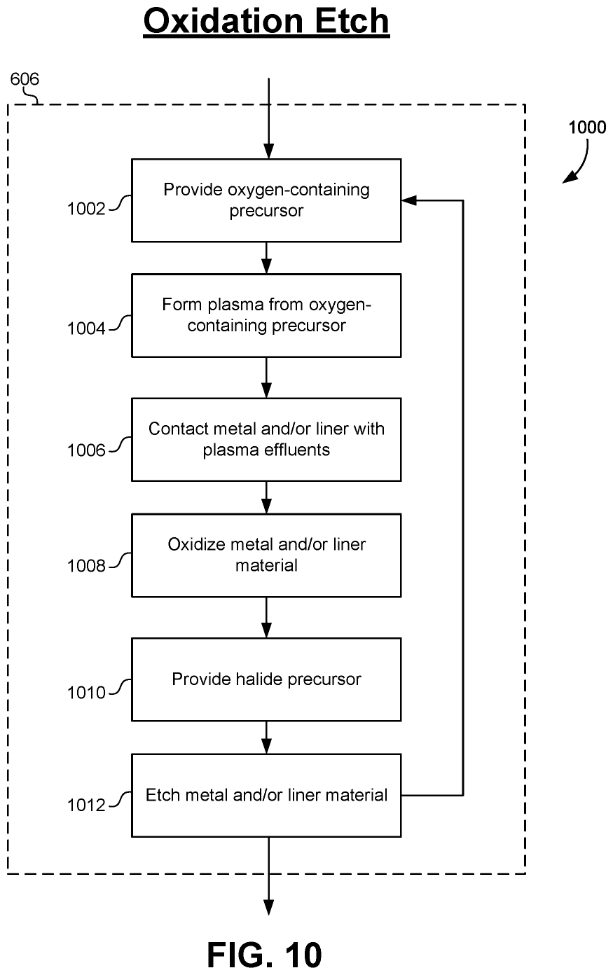

The method 600 may also include fluorination with a protective gas to etch the material 745, the metal 440, and/or the liner 451 (604). FIG. 8 illustrates a flowchart of a method 800 for performing a fluorination etch with the protective gas, according some embodiments. Method 800 may describe operations shown schematically in FIG. 9, the illustrations of which will be described in conjunction with the operations of method 800. It is to be understood that the figures illustrate only partial schematic views, and a substrate may contain any number of additional materials and features having a variety of characteristics and aspects as illustrated in the figures.

The method may be performed to etch or otherwise remove portions of the material 745, the metal 440, and/or the liner 451, which may separate the structure into the recessed portions of the structure. The method may be performed to facilitate control of the profile through the structure, and improve etch characteristics, such as surface smoothness of the metal within the recessed sections of the structure. For example, the method 800 may include flowing a fluorine-containing precursor and a secondary gas, such as a protective gas, into a processing region of the chamber in which the substrate is maintained (802). The fluorine-containing precursor and the secondary gas may contact the substrate (804), and etch the metal within the high aspect-ratio structure (806). As illustrated in FIG. 9, metal 440 may be recessed within the trench along sidewalls of the memory hole, as well as along a top surface across the structure. While conventional technologies may create a top-to-bottom loading that may resemble a V-shaped profile, where more material is etched at the top of the structure as discussed above, the present technology may afford a substantially or essentially straight profile, as well as an inverted V-shaped profile, where the material further into the structure may be etched more than material at the top of the structure, which may allow the formation of a range of top-to-bottom loading values. The metal may include Mo, TiN, W, or any other type of metal.

To provide this control, the present technology may utilize a secondary gas that may help limit or reduce etching or etch rates at the top of the structure. For example, the fluorine-containing precursor and the secondary gas may access the metal 440 along an exterior top surface into which the memory hole is formed prior to contacting metal within the feature. Without the secondary gas, which may be a protective gas, the etching may begin at the top of the structure long before the etching may begin nearer the bottom of the structure. However, by incorporating a secondary gas, the secondary gas molecules may occupy surface area or sites along the metal 440, which may reduce etch rates. For example, although fluorine may continue to bond with the metal at discreet locations, these locations may be at least partially blocked by the secondary gas. Exemplary metals, such as molybdenum or tungsten, may not have one-to-one removal characteristics with fluorine, and instead, three, four, or six fluorine atoms may be incorporated prior to removal of the metal atoms. This method may also be used with TiN as the metal 440. Accordingly, by utilizing the protective gas, these interactions between the fluorine and the metal 440 may be controlled, reduced, or limited, which may facilitate control of the etch rate.

However, as the flow rate ratio of the secondary gas increases relative to the fluorine-containing precursor, the etch rate may continue to reduce, and eventually the secondary gas molecules will interrupt the etch process at each location, preventing further etch. Accordingly, in some embodiments a flow rate ratio of the fluorine-containing precursor to the secondary gas may be maintained greater than or about 1:1, which may ensure an amount of etch proceeds at the top of the structure. For example, the flow rate ratio of the fluorine-containing precursor to the secondary gas may be maintained at greater than or about 1.2:1, and may be maintained at greater than or about 1.4:1, greater than or about 1.6:1, greater than or about 1.8:1, greater than or about 2.0:1, greater than or about 2.2:1, greater than or about 2.4:1, greater than or about 2.6:1, greater than or about 2.8:1, greater than or about 3.0:1, greater than or about 4.0:1, greater than or about 5.0:1, greater than or about 6.0:1, greater than or about 7.0:1, greater than or about 8.0:1, greater than or about 9.0:1, greater than or about 10.0:1, or greater. Additionally, a first flow rate ratio may be used, and may be adjusted as the etch process proceeds to a second flow rate ratio different from the first as the etch process proceeds. Any of the noted ratios, or any ratio encompassed within the ranges listed may be used for either the first flow rate ratio or the second flow rate ratio in some embodiments during the flowing operations.

In some embodiments, the fluorine-containing precursor and/or the secondary gas may be plasma enhanced prior to contacting the metal on the substrate. The plasma may be formed in a remote region of the processing chamber, or may be formed locally. Although a substrate-level plasma may be produced, in some embodiments the plasma may be a remote plasma, which may protect exposed substrate materials from ion bombardment that may occur due to the substrate-level plasma. Whether plasma-enhanced or not, the materials may contact the metal 440, at the top of the structure and then may flow through the structure into the memory holes. The etch process may continue until the metal is removed towards the recesses extending laterally and perpendicular to a direction of the memory hole. Although the process may be continued to recess the metal further into each recess and separate the cells through the memory hole, in some embodiments method 800 may include a secondary etch process to fully separate the cells and etch laterally within the recesses. Because memory holes may be extending to several micrometers in depth, etchants may lose energy flowing deeper into the structure, and laterally into the recessed features, which may further slow etching, and potentially lower selectivity to the exposed surfaces of the dielectric materials exposed on several sides. Accordingly, in a second operation the etchant may be adjusted to perform a second recess operation.

Oxidation with Fluorination/Chlorination

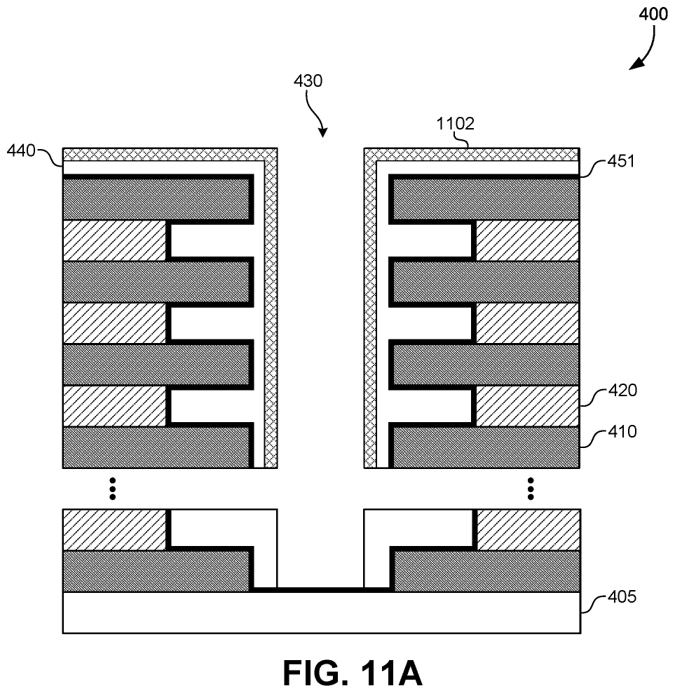

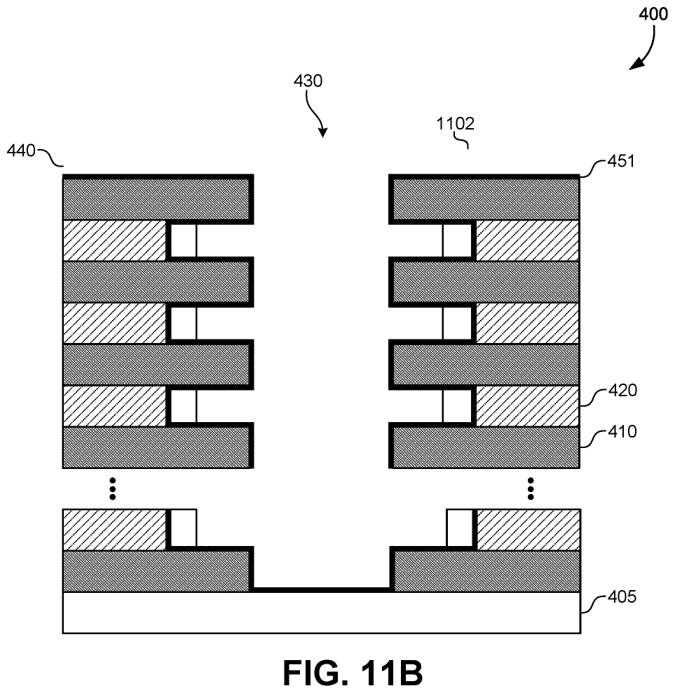

FIG. 10 illustrates a method 1000 for performing an oxidation etch, according to some embodiments. The operations of method 1000 will now be described in conjunction with the schematic illustration of FIGS. 11A-11B. The method 1000 may include initially oxidizing the metal formed on the top, bottom, and/or sidewalls of the trench 430 to form a metal oxide 1102 inside and on top of the trench 430. In some embodiments, to oxidize metal, the substrate 405 may be positioned within a processing region of a semiconductor processing chamber, such as the substrate processing region 233 of the processing chamber system 200 discussed above with reference to FIG. 2A. Once positioned within the processing region, the method 1000 may be initiated by providing an oxygen-containing precursor to a remote plasma region of the semiconductor processing chamber (1002). The remote plasma region may be fluidly coupled with the processing region, although it may be physically partitioned to limit plasma at the substrate level, which may damage exposed structures or materials on the substrate 405. In some embodiments, the remote plasma region may include a remote plasma system (RPS) fluidly coupled with an inlet to the semiconductor processing chamber, such as the RPS 201 discussed above. In some embodiments, the remote plasma region may include a capacitively-coupled plasma (CCP) region, such as the first plasma region 215 formed by capacitively coupling the faceplate 217 and the showerhead 225 and/or ion suppressor 223, and the CCP region may be physically separated from the processing region by one of its electrodes, such as the showerhead 225 and/or ion suppressor 223. The method 1000 may further include forming a plasma of the oxygen-containing precursor (1004) to produce oxygen-containing plasma effluents, and providing the oxygen-containing plasma effluents to the processing region (1006). The metal may be oxidized (1008) to form the metal oxide 1102 inside and on top of the trench 403 as shown in FIG. 11A.

The oxygen-containing precursor may include a variety of fluids, and may include one or more of atomic oxygen, molecular oxygen (O₂), N₂O, NO, NO₂, CO₂, ozone (O₃), or any other oxygen-containing precursor that may similarly perform the oxidation operation. The oxygen-containing precursor may be provided at a rate of at least 1000 sccm, and may be provided at a rate greater than or about 2000 sccm, greater than or about 3000 sccm, greater than or about 4000 sccm, greater than or about 5000 sccm, greater than or about 6000 sccm, greater than or about 7000 sccm, greater than or about 8000 sccm, greater than or about 9000 sccm, or more in embodiments. In some embodiments, the flow of the oxygen-containing precursors may be pulsed. The flow of the oxygen-containing precursors may be pulsed for time periods of less than or about 60 seconds in embodiments, and may be pulsed for time periods of less than or about 55 seconds, less than or about 50 seconds, less than or about 45 seconds, less than or about 40 seconds, less than or about 35 seconds, less than or about 30 seconds, less than or about 25 seconds, less than or about 20 seconds, less than or about 15 seconds, less than or about 10 seconds, less than or about 5 seconds, or less.

During the flow of the oxygen-containing precursors, the flow rate of the oxygen-containing precursor may be maintained at relatively high levels such that sufficient or even more than sufficient oxygen may be present from the top to the bottom of the trenches to fully oxidize the molybdenum connecting the molybdenum regions. In some embodiments, ample supply of oxygen may further improve the uniformity of the thickness of the molybdenum oxide layer formed inside the trenches. The uniformity may occur in part due to the initial rapid oxidization occurring at the neat or clean molybdenum surface. Specifically, the method 1000 may be performed after metal has been deposited inside the trenches but before any atmospheric exposure. The oxidation rate at the metal surface may be sufficiently rapid that with ample supply of oxygen, the metal proximate the bottom of the trenches may be almost simultaneously oxidized to a thickness that may be substantially the same as that of the metal oxidized proximate the top of the trenches. As oxidation penetrates the surface of the metal, the oxidation rate may decrease dramatically, and may in some embodiments reach a saturation depth at which minimal or no further oxidation may continue to occur at chamber conditions. Accordingly, metal located at a location further from initial contact of the plasma effluents, such as at the bottom of the trench, may be oxidized to a similar or substantially similar depth as at the top of the trench despite the longer residence time at locations proximate the top of the trench.

In some embodiments, the initial rapid oxidization may produce a metal oxide layer having a thickness of greater than or about 10 Å, greater than or about 15 Å, greater than or about 20 Å, greater than or about 25 Å, greater than or about 30 Å, greater than or about 35 Å, greater than or about 40 Å, greater than or about 50 Å, greater than or about 60 Å, greater than or about 70 Å, greater than or about 80 Å, greater than or about 90 Å, greater than or about 100 Å, or more, before the oxidization process slows down. In some embodiments, by adjusting the processing conditions, the initial rapid oxidization may produce a metal oxide layer having a thickness of less than or about 100 Å, less than or about 900 Å, less than or about 80 Å, less than or about 70 Å, less than or about 60 Å, less than or about 50 Å, less than or about 40 Å, or less. The thickness of the molybdenum oxide layer proximate an upper region of the trenches may differ from the thickness of the metal oxide layer proximate a lower region of the trenches by less than or about 30%, less than or about 25%, less than or about 20%, less than or about 15%, less than or about 10%, less than or about 5%, less than or about 3%, less than or about 1%, or less in embodiments. Accordingly, a ratio of less than or about 1.3:1, less than or about 1.25:1, less than or about 1.2:1, less than or about 1.15:1, less than or about 1.1:1, less than or about 1.05:1, or a ratio of substantially or essentially 1:1 top to bottom loading of metal oxidation as shown in FIG. 11A may be achieved utilizing the method 1000. Given the initial rapid oxidation, the flow of the oxygen-containing precursor may be maintained for time periods of less than or about 15 minutes, less than or about 10 minutes, less than or about 5 minutes, less than or about 3 minutes, less than or about 2 minutes, less than or about 90 seconds, less than or about 60 seconds, less than or about 50 seconds, less than or about 40 seconds, less than or about 30 seconds, less than or about 25 seconds, less than or about 20 seconds, less than or about 15 seconds, less than or about 10 seconds, less than or about 5 seconds, or less. In some embodiments, to facilitate sufficient oxidation, the flow of the oxygen-containing precursor may be maintained for time periods greater than or about 5 seconds, greater than or about 10 seconds, greater than or about 30 seconds, greater than or about 1 minute, greater than or about 5 minutes, greater than or about 10 minutes, greater than or about 15 minutes, or more. Accordingly, in some embodiments, the flow of the oxygen-containing precursor may be maintained between about 5 seconds and about 15 minutes, between about 30 seconds and about 10 minutes, between about 1 minute to about 5 minutes, or any other suitable time period.

The oxygen-containing precursor may also include any number of carrier gases, which may include nitrogen, helium, argon, or other noble, inert, or useful precursors. The carrier gases may be used to enhance uniform distribution of the oxygen-containing precursor inside the trenches, which may further improve top to bottom loading for the oxidation operation (1008). In some embodiments, a flow rate of the carrier gas may be maintained less than or about 50% of the oxygen-containing precursor flow rate, or may be less than or about 40%, less than or about 30%, less than or about 20%, less than or about 10%, less than or about 5%, less than or about 3%, or less than or about 1% of the oxygen-containing precursor flow rate, or less. By adjusting the composition and/or the respective flow rates of the components of the oxygen-containing precursor, uniform delivery of the oxygen-containing plasma effluents inside the trench may be achieved, thereby further improving the uniformity of metal oxidation from the top to the bottom of the trenches.

Other process conditions may also impact the uniformity of metal oxidation from the top to the bottom of the trenches, such as plasma power, operating temperature, operating pressure, etc. In embodiments where the oxygen-containing plasma may be formed in a remote plasma system, the plasma power may be less than or about 2,000 W, and may be less than or about 1,500 W, less than or about 1,000 W, less than or about 750 W, less than or about 500 W, less than or about 250 W, or less, to facilitate the dissociation of the oxygen-containing precursors. In embodiments where the oxygen-containing plasma may be formed in a capacitively-coupled plasma (CCP) region of the semiconductor processing chamber, lower plasma powers may be utilized so as to prevent damage to structures on the substrate. The plasma power in the CCP region may be at least 50 W, and may be greater than or about 100 W, greater than or about 150 W, greater than or about 200 W, greater than or about 250 W, greater than or about 300 W, greater than or about 350 W, greater than or about 400 W, greater than or about 450 W, greater than or about 500 W, or more in embodiments. The plasma power in the CCP region may be less than or about 2,500 W, and may be less than or about 2,000 W, less than or about 1,500 W, less than or about 1,000 W, less than or about 750 W, less than or about 500 W, less than or about 250 W, or less.

To facilitate rapid oxidation and thereby improve top to bottom loading, the temperature within the processing chamber or at the substrate level may be maintained between about 200° C. and about 600° C. in embodiments. The temperature may be maintained above or about 200° C., and may be maintained above or about 250° C., above or about 300° C., above or about 350° C., above or about 400° C., above or about 450° C., above or about 500° C., above or about 550° C., above or about 600° C., or higher. The higher the temperature that may be maintained during the oxidation operation, the faster the metal may be oxidized, and the more uniform the thickness of the metal oxide layer may be. During the oxidation operation, a pressure within the processing chamber may be maintained below or about 20 Torr in embodiments. The pressure may be maintained below or about 15 Torr, and may be maintained below or about 10 Torr, below or about 5 Torr, below or about 4 Torr, below or about 3 Torr, below or about 2 Torr, below or about 1 Torr, below or about 100 mTorr, or lower. In embodiments the pressure may be maintained between about 500 mTorr and about 10 Torr. Maintaining a relatively low pressure inside the processing chamber may facilitate the distribution of the oxygen-containing plasma effluents into the trench, resulting in uniform top to bottom oxidation as discussed above.

Although this method oxidizes the metal and/or liner material using oxygen-containing plasma, a non-plasma process may be utilized. Accordingly, in some embodiments, operations 1004 and 1006 of the method 1000 may be omitted. The oxygen-containing precursor, such as one or more of atomic oxygen, molecular oxygen (O₂), ozone (O₃), or other oxygen-containing precursors, may be provided to the processing region to oxidize the metal and/or liner material. In the embodiments where molecular oxygen may be utilized for oxidizing the metal and/or liner material, the temperature within the processing chamber or at the substrate level may be maintained between about 250° C. and about 600° C. The temperature may be maintained above or about 250° C., and may be maintained above or about 300° C., above or about 350° C., above or about 400° C., above or about 450° C., above or about 500° C., above or about 550° C., above or about 600° C., or higher. In the embodiments where ozone may be utilized for oxidizing the metal and/or liner material, the ozone may be produced using an ozonator, which may be fluidly coupled with an inlet of the processing chamber.

Given the ample supply of the oxygen-containing precursor and proper operating conditions, in some embodiments, substantially all the metal liner formed on the sidewalls of the trench 430 may be oxidized, and portions of the metal regions inside the lateral recesses of the trench 430 may also be oxidized, as illustrated in FIG. 11B. Slightly etching the metal inside the lateral recesses may ensure separation of the metal regions when the oxidized metal may be removed in subsequent operations of the method 1000. As is also shown in FIG. 5B, during the oxidation operation 1008, when the oxide or nitride barriers include nitride, portions of the oxide or nitride barriers contacting the metal oxide 1102 may also be oxidized to form oxidized portions of nitride barriers.

Once the liner on at least a portion of the sidewalls of the trench 430 is oxidized, along with portions of the metal in some embodiments, the oxidization operation (1008) may be paused by halting the flow of the oxygen-containing precursor. In some embodiments, residual plasma effluents may be purged prior to further operations. A halide precursor may be provided to the processing region (1010). The halide precursor may include a metal halide or other halogen-containing precursors that may interact with the metal oxide and/or the liner material. In some embodiments, the halide precursor may be or include a chlorine-containing precursor or a fluorine-containing precursor. The halide precursor may include tungsten chloride, such as tungsten pentachloride, and/or tungsten fluoride, such as tungsten hexafluoride. The halide precursor may modify and interact with the metal oxide 1102 to form volatile substances (1012), which may then be removed from the chamber. The volatile substances formed from the halide precursor and the metal oxide 1102 may include, for example, molybdenum oxychloride, molybdenum oxyfluoride, titanium nitride materials, and so forth. Once the metal oxide 1102 is removed by the halide precursor, the underlying oxide or nitride barriers, which may also be oxidized as discussed above, may be exposed. Although the exposed portions of the oxide or nitride barriers may interact with the halide precursor without being first oxidized, oxidation of the oxide or nitride barriers to form oxidized portions of nitride barriers may improve the etch rate.

The etch rate of oxidized portions of the liner material by the halide precursor may be at least about 2 times, about 3 times, about 4 times, about 5 times, about 6 times, about 7 times, about 8 times, or more of the etch rate of non-oxidize portions of the liner material by the halide precursor. The volatile substances formed from the halide precursor and the oxidized portions of nitride barriers may include a metal oxychloride, a metal oxyfluoride, a metal chloride, such as a metal tetrachloride, and/or a metal fluoride, such as a metal tetrafluoride. The halide precursor may be delivered during operation 1010 for a time period between about 15 seconds and about 5 minutes. The halide precursor delivery may last at least about 30 seconds, 1 minute, 1.5 minutes, 2 minutes, 2.5 minutes, 3 minutes, 3.5 minutes, 4 minutes, 4.5 minutes, 5 minutes, or longer in embodiments to ensure complete removal of the metal oxide 1102 and/or the oxidized portions of the nitride barriers. As shown in FIG. 5B, the metal oxide 1102 and/or the oxidized portions of the nitride barriers may be removed upon completion of etching operation 1012, and the metal regions may be separated from one another.

At the etching operation 1012, the metal oxide 1102 and the oxidized portions of nitride barriers may be selectively removed relative to the other materials and structures on the substrate, including the metal regions, the oxide or nitride barriers interposed between the metal regions and the gate dielectric, and the gate dielectric. Without intending to be bound to any particular theory, the gate dielectric may not be etched by the halide precursor partly because the bonding between oxygen and metal in the gate dielectric may be stronger than the bonding between oxygen and metal and/or the bonding between oxygen and metal in the gate dielectric, and partly because the reactive products, if any, may include metal fluorides and/or metal oxyfluorides, which may be substantially non-volatile under the operating conditions for the etch operation 1012. Although not explicitly illustrated in FIG. 11B, the method 1000 may also selectively remove the metal oxide 1102 and the oxidized portions of nitride barriers relative to silicon oxide, and relative to silicon nitride, which may form the charge trap layers for the memory cells.

Because the halide precursor may selectively etch only the metal oxide 1102 and/or the oxidized portions of nitride barriers, and because the oxidation operation 1008 may yield substantially uniform top to bottom loading as discussed above, the etching operation 1012 may also yield substantially uniform top to bottom loading. The etched thickness of the metal layer proximate an upper region of the trenches may differ from the etched thickness of the metal layer proximate a lower region of the trenches etched by method 400 by less than or about 30%, less than or about 25%, less than or about 20%, less than or about 15%, less than or about 10%, less than or about 5%, less than or about 3%, less than or about 1%, or less in embodiments. Accordingly, a ratio of less than or about 1.3:1, less than or about 1.25:1, less than or about 1.2:1, less than or about 1.15:1, less than or about 1.1:1, less than or about 1.05:1, or a ratio of substantially or essentially 1:1 top to bottom loading of metal etching may be achieved utilizing the method 1000. Such uniform top to bottom loading may prevent or limit over-etching of the metal regions inside the lateral recesses of the trench 430 while facilitating complete removal of the metal that may be deposited on the sidewalls and/or the bottom of the trench 430 to ensure separation of the metal regions from each other.

Additionally, using the halide precursor as the etchant may further improve the top to bottom loading due to the isotropic etching it may offer. As compared to conventional reactive ion etching methods, which may impart directionality and make it difficult to laterally etch the metal oxide 1102 and/or the oxidized portions of nitride barriers lining the sidewalls of the trench 430, the halide precursor may react with the metal oxide 1102 and/or the oxidized portions of nitride barriers substantially uniformly inside the trench 430, resulting in a virtually isotropic etching of the metal oxide 1102 and/or the oxidized portions of nitride barriers inside the trench 430. Such uniformity may be facilitated by maintaining a pressure within the processing chamber above or about 10 Torr, above or about 15 Torr, above or about 20 Torr, above or about 25 Torr, above or about 30 Torr, above or about 35 Torr, above or about 40 Torr, above or about 45 Torr, above or about 50 Torr, above or about 55 Torr, above or about 60 Torr, above or about 70 Torr, above or about 80 Torr, above or about 90 Torr, above or about 100 Torr, or higher. Higher pressure inside the processing chamber may reduce the mean free path of the halide precursor and may achieve a non-directional flow of the halide precursor, thereby achieving the isotropic etching inside the trenches. Alternatively, in some embodiments, during the etching operation, the pressure within the processing chamber may be maintained below or about 100 Torr, below or about 90 Torr, below or about 80 Torr, below or about 70 Torr, below or about 60 Torr, below or about 55 Torr, below or about 50 Torr, below or about 45 Torr, below or about 40 Torr, below or about 35 Torr, below or about 30 Torr, below or about 25 Torr, below or about 20 Torr, below or about 15 Torr, below or about 10 Torr, below or about 5 Torr, below or about 1 Torr, or lower. Accordingly, in some embodiments, the method 1000 may further include adjusting the operating conditions (e.g., temperature, pressure, both, etc.) within the processing chamber between the oxidation operation and the etching operation. For example, in some embodiments, the pressure may be adjusted from below or about 5 Torr during the oxidation, to a pressure above or about 10 Torr. Any of the previously discussed pressures or ranges may similarly be used during the two operations.

As discussed above, a relatively higher temperature may be maintained within the processing chamber or at the substrate level during the oxidation operation 1008 of the method 1000 to facilitate uniform oxidation. In some embodiments, during the etching operation 1012, a relatively lower temperature may be maintained within the processing chamber or at the substrate level. Due to the high volatility of the byproducts formed using the halide precursor, a higher temperature may not be required for effective etching to be achieved. Additionally, a relatively lower temperature may also limit or prevent surface migration of any non-volatile or less volatile byproducts that may be formed, such as a metal fluoride as discussed above. During the etching operation, the temperature within the processing chamber or at the substrate level may be maintained between about 250° C. and about 400° C. during the etching operation 1012. In some embodiments, the temperature may be maintained below or about 400° C., and may be maintained below or about 350° C., below or about 300° C., below or about 250° C., or lower in embodiments. In some embodiments, to increase reaction rates, a relatively higher temperature may be maintained within the processing chamber or at the substrate level during the etching operation. In some embodiments, the temperature maintained within the processing chamber or at the substrate level during the etching operation may be similar to or even greater than the temperature maintained within the processing chamber or at the substrate level during the oxidation operation. Accordingly, during the etching operation, the temperature within the processing chamber or at the substrate level may be maintained greater than or about 400° C., greater than or about 450° C., greater than or about 500° C., greater than or about 550° C., greater than or about 600° C., or even higher.

There may be several ways to maintain different temperatures in the processing chamber or at the substrate level during the oxidation operation and the etching operation. When the oxidation operation 1008 may be paused, the temperature in the processing chamber or at the substrate level may be lowered or increased to a desired level before initiating the flow of the halide precursor at operation 1010. Alternatively or additionally, in some embodiments, during the oxidation operation 1008, the substrate may be positioned close to a heating source inside the processing chamber so as to achieve a relatively high temperature at the substrate level, and subsequent to the oxidation operation 1008, the substrate may be moved away from the heating source so as to lower the temperature at the substrate level for the etching operation 1012. For example, showerhead 225 may include a heater or may be configured to be heated in some embodiments. During the oxidation operation, the substrate may be positioned proximate the showerhead to increase the substrate and operating temperature, and the substrate may be positioned at a first distance from the heating source. Subsequent to the oxidation operations, the substrate may be translated away from the showerhead to a second distance from the heating source, such as by lowering a pedestal height, to reduce the heating effect. The etching operation may then be performed at a second temperature lower than the first temperature when the substrate is moved. In some embodiments where the etching operation 1012 may be performed at a higher temperature than the oxidation operation 1008, the substrate may be positioned further away from the heating source inside the processing chamber so as to achieve a relatively lower temperature at the substrate level during the oxidation operation 1008, and subsequent to the oxidation operation 1008, the substrate may be moved closer to the heating source so as to increase the temperature at the substrate level for the etching operation 1012.

In still other embodiments, the oxidation operation 1008, as well as operation 1002 and optionally, operations 1004 and 1006 for producing the oxygen-containing plasma effluents, may be performed in a chamber separate from the chamber to which the halide precursor may be providing at operation 1010 to start the etching operation 1012. Utilizing two chambers maintained at different temperatures for the oxidation operation 1008 and the etching operation 1012, respectively, may involve extra time for transporting the substrate from one chamber to the other. However, processing time may be saved due to the fact that no temperature adjustment may be required inside each chamber and sufficient oxidation may be ensured in one cycle, thereby reducing overall processing time.

In some embodiments, depending on the thickness of the liner formed on at least a portion of the sidewalls of the trench, the method 1000 may be performed in cycles to facilitate complete oxidation and removal of the molybdenum outside the lateral recesses to ensure separation of the molybdenum regions from one another. As shown in FIG. 10, the method 1000 may include repeating the oxidation operations 1002-1008 and the etch operations 1010-1012. As discussed above, depending on the processing conditions, the initial rapid oxidization of neat or clean metal may produce a metal oxide layer having a thickness between about 10 Å and about 400 Å or more before the oxidization process slows down. To improve processing efficiency, oxidation of the metal may be paused after the initial rapid oxidization, and removal of the oxidized metal may be initiated. After removal of the metal, the flow of the oxygen-containing precursor may be resumed to initiate another cycle of the method 1000. In some embodiments, two or more cycles, such as three cycles, four cycles, five cycles, or more, of oxidation and removal operations may be performed to achieve complete removal of the first liner formed on at least a portion of the sidewalls of the trenches.

Turning back to FIG. 6, operation 602, 604, and 606 may be repeated individually and/or together in any combination. For example, the process may selectively deposit material (602), perform the fluorination with protected gas etch (604), and perform the oxidation/halide etch (606) in sequence multiple times to fully remove the metal to the desired amount. Further, the individual steps may be repeated individually as part of the method 600 before moving on to a subsequent step. For example, the oxidation/halide etch (606) may be performed repeatedly before cycling back to operation 602.

### Post Treatment

In some embodiments residual fluorine may be incorporated in the remaining metal either after the etch processer. Accordingly, in some embodiments a post treatment operation may be performed (608), which may occur subsequent to any of the other processes in the method 600. For example, the post treatment operations 608 may be performed after operation 602, after operation 604, and/or after operation 606, collectively or individually. For example, a chlorine-containing precursor, such as boron trichloride, may be flowed into the processing chamber. The chlorine-containing precursor may or may not be plasma enhanced in embodiments, and if plasma enhanced, the plasma may be generated remotely or in situ within the processing chamber. The chlorine-containing precursor may contact the substrate, and may interact with the surface of the metal remaining to scavenge any residual fluorine in some embodiments of the present technology.

Exemplary fluorine-containing precursors may include one or more of fluorine or chlorine in some embodiments, as well as any other halogen. Some exemplary precursors that may be utilized may include halides including hydrogen fluoride, nitrogen trifluoride, or any organofluoride, diatomic fluorine, bromine trifluoride, chlorine trifluoride, sulfur hexafluoride, xenon difluoride, boron trichloride, tungsten pentachloride, tungsten hexachloride, or any other fluorine-containing precursor. A chlorine-containing precursor may be included or substituted for a fluorine-containing precursor as well, and boron trichloride, diatomic chlorine, or other chlorine-containing precursors may be used. The precursors may also be flown together in a variety of combinations. For example, as noted previously the second fluorine-containing precursor may more readily donate fluorine relative to the first fluorine-containing precursor. As one non-limiting example of precursors, the first fluorine-containing precursor may be or include nitrogen trifluoride, while the second fluorine-containing precursor may be or include tungsten hexafluoride or sulfur hexafluoride.

The precursors may also be flowed with any number of additional precursors or carrier gases including diatomic hydrogen, or a hydrogen-containing precursor, nitrogen, argon, helium, or any number of additional materials, although in some embodiments the precursors may be limited to control side reactions or other aspects that may impact selectivity. The secondary gas provided during the etch process may include oxygen-containing precursors and/or nitrogen-containing precursors. For example, non-limiting oxygen-containing precursors may include diatomic oxygen, ozone, water, an alcohol, hydrogen peroxide, nitrous oxide, nitric oxide, or any other oxygen-containing material. Non-limiting nitrogen-containing precursors may include diatomic nitrogen, or any oxygen-containing precursor that also includes nitrogen, for example.

By utilizing precursors and processing as discussed throughout the present technology, metal used in 3D NAND and other semiconductor structures may be more uniformly etched from between sections of dielectric material, such as silicon oxide, while limiting the damage or removal of silicon oxide, and maintaining improved profile or top-to-bottom loading value. For example, in some embodiments of the present technology, either after the first etch process or the second, a top-to-bottom loading value may be maintained at less than or about 2:1, and may be maintained at less than or about 1.8:1, less than or about 1.6:1, less than or about 1.5:1, less than or about 1.4:1, less than or about 1.3:1, less than or about 1.2:1, less than or about 1.1:1, or about 1.0:1, indicating an equivalent etch at locations nearer the top of the structure as well as nearer the bottom of the structure. By using the term “about”, the present disclosure intends to encompass the limitations of measurement at form factors discussed throughout the present technology, which may not provide perfect precision in measurement, although the generally identified conditions are understood. Additionally, in some embodiments, the etch processes may be further tuned as noted above to produce either a V-shaped profile, or an inverted V-shaped profile, in which a top-to-bottom loading value may be maintained at less than or about 0.9:1, and may be maintained at less than or about 0.8:1, less than or about 0.7:1, less than or about 0.6:1, less than or about 0.5:1, or less.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology. Additionally, methods or processes may be described as sequential or in steps, but it is to be understood that the operations may be performed concurrently, or in different orders than listed.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a precursor” includes a plurality of such precursors, and reference to “the layer” includes reference to one or more layers and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

What is claimed is:

1. A method of pre-treating metal surfaces prior to etching in 3D NAND structures, the method comprising:
providing an oxygen-containing precursor to a semiconductor processing chamber, wherein a substrate is positioned within the semiconductor processing chamber, wherein the substrate comprises:
a trench formed between columns; and
a metal formed in at least one of the columns;
contacting the metal with the oxygen-containing precursor to form an oxidized portion of the metal;
providing a halide precursor to the semiconductor processing chamber; and
contacting the oxidized portion of the metal with the halide precursor to remove the oxidized portion of the metal from a sidewall of the trench.

2. The method of claim 1, further comprising:
prior to providing the oxygen-containing precursor to the semiconductor processing chamber, providing a helium treatment to the metal to bombard a surface of the metal and remove residue on the surface of the metal.

3. The method of claim 2, wherein the helium treatment is provided without a plasma present.

4. The method of claim 2, wherein the helium treatment is provided with a plasma present.

5. The method of claim 1, wherein the oxygen-containing precursor comprises one or more of atomic oxygen, molecular oxygen (O₂), N₂O, NO, NO₂, CO₂, or ozone (O₃).

6. The method of claim 1, wherein the oxidized portion of the metal is less than or about 100 Å.

7. The method of claim 1, wherein the halide precursor comprises WF₆ or Cl₃, and contacting the oxidized portion of the metal with the halide precursor is performed without a plasma with a temperature between about 200° C. and about 500° C.

8. The method of claim 1, further comprising, after contacting the oxidized portion of the metal with the halide precursor, treating the metal with hydrogen to remove residual metal oxide on a surface of the metal, wherein treating the metal with hydrogen does not substantially etch the metal.

9. A method of etching memory holes in 3D NAND structures, the method comprising:
priming an exposed metal within a high aspect-ratio structure defined on a substrate, wherein the priming comprises oxidizing the exposed metal to form a layer of metal oxide, etching the metal oxide with a halide precursor, and treating the exposed metal with hydrogen to remove residual halide material;
depositing a material along surfaces of the exposed metal within a high aspect-ratio structure defined on a substrate, wherein the material is formed thicker along surfaces near an opening of the high aspect-ratio structure than along surfaces deeper within the high aspect-ratio structure; and
repeatedly oxidizing a surface of the exposed metal and etching an oxidized portion of the exposed metal to conformally etch the exposed metal uniformly throughout the high aspect-ratio structure.

10. The method of claim 9, wherein priming the exposed metal further comprises, prior to oxidizing the exposed metal, providing a helium treatment to the exposed metal to bombard a surface of the exposed metal and remove residue on the surface of the exposed metal.

11. The method of claim 9, wherein priming the exposed metal further comprises, after contacting the oxidized portion of the exposed metal with the halide precursor, treating the exposed metal with hydrogen to remove residual metal oxide on a surface of the exposed metal, wherein treating the exposed metal with hydrogen does not substantially etch the exposed metal.

12. The method of claim 9, wherein oxidizing the surface of the exposed metal comprise:
flowing a first fluorine-containing precursor and a secondary gas into a processing region of a semiconductor processing chamber; and
contacting the exposed metal with the first fluorine-containing precursor and the secondary gas.

13. The method of claim 12, wherein the secondary gas may be a protective gas comprising oxygen or nitrogen.

14. The method of claim 9, further comprising, after repeatedly oxidizing the surface of the exposed metal and etching the oxidized portion of the exposed metal, performing a post-treatment of the high aspect-ratio structure using a fluorine-containing precursor.

15. The method of claim 14, further comprising forming a plasma from the fluorine-containing precursor to remove any residual fluorine.

16. A method of pre-treating metal surfaces prior to etching in 3D NAND structures, the method comprising:
providing a helium precursor to a semiconductor processing chamber, wherein a substrate is positioned within the semiconductor processing chamber, the substrate comprises a memory hole for a 3D NAND and the helium precursor treats a metal in the memory hole to bombard a surface of the metal and remove residue on the surface of the metal;
providing a hydrogen precursor to the semiconductor processing chamber to remove residue on the surface of the metal;
providing an oxygen-containing precursor and contacting the metal with the oxygen-containing precursor to form an oxidized portion of the metal;
providing a halide precursor to the semiconductor processing chamber and contacting the oxidized portion of the metal with the halide precursor to remove the oxidized portion of the metal from a sidewall of the memory hole; and
treating the metal with hydrogen to remove residual metal oxide on a surface of the metal.

17. The method of claim 16, further comprising:
depositing a material along surfaces of the metal within the memory hole, wherein the material is formed thicker along surfaces near an opening of the memory hole than along surfaces deeper within the memory hole.

18. The method of claim 17, further comprising:
repeatedly oxidizing a surface of the metal and etching an oxidized portion of the metal to conformally etch the metal uniformly throughout the memory hole.

19. The method of claim 18, further comprising:
after repeatedly oxidizing the surface of the metal and etching the oxidized portion of the metal, performing a post-treatment of the memory hole using a fluorine-containing precursor.

20. The method of claim 19, further comprising forming a plasma from the fluorine-containing precursor to remove any residual fluorine.
